(19) United States
(12) Patent Application Publication
(10) Pub. No.: US 2018/0131162 A1
(43) Pub. Date: May 10, 2018

(54) ISOLATED ELECTRICAL COMPARTMENT (IEC) FOR POWER DISTRIBUTION UNITS

(71) Applicant: POWER DISTRIBUTION, INC., Richmond, VA (US)

(72) Inventors: Adam Rey DOMINGUEZ, Santa Clara, CA (US); Yasushi Richard SHIMABUKURO, Tustin, CA (US)

(73) Assignee: POWER DISTRIBUTION, INC., Richmond, VA (US)

(21) Appl. No.: 15/806,824

(22) Filed: Nov. 8, 2017

Related U.S. Application Data
(60) Provisional application No. 62/419,255, filed on Nov. 8, 2016.

(51) Int. Cl. H02B 1/38; H02G 3/06; H05K 5/02

(52) U.S. Cl. CPC H02B 1/38; H05K 5/0221; H02G 3/0616

(57) ABSTRACT

An isolated electrical compartment attachable to a power distribution unit. The isolated electrical compartment including a housing defining a cavity, having a plurality of access doors, and having a plurality of conduit service openings positioned on a top surface or a side surface of the power distribution unit, each of the plurality of access doors corresponding to one of the plurality. of conduit service openings. The isolated electrical compartment also including a plurality of nonconductive walls positioned within the cavity and forming a plurality of access compartments, each access compartment being accessible using one of the plurality of access doors.

This application claims the benefit of provisional U.S. Patent Appl. Ser. No. 62/419,255, filed Nov. 8, 2016.

### BACKGROUND OF THE INVENTION

### 1. Field of the Invention

The present invention relates to an improved safety compartment for electrical components and more particularly to an isolated electrical compartment. (IEC) for power distribution units.

### 2. Description of Related Art

Power distribution units (PDUs) are generally used to provide large amounts of power to a number of electronic components (e.g., servers). These PDUs have numerous connections that are used to connect to cables that are routed to a number of electronic components. These connections have large amounts of current travelling through them. Therefore, in order to provide safe connections and disconnections, the PDUs or a portion thereof, may need to be shut down or deactivated in order to provide safe connections or disconnections to the number of electronic components. Shutting down the PDUs or a portion thereof, however, may be disadvantageous in that is wastes time and resources.

### SUMMARY OF THE INVENTION

According to some embodiments, an isolated electrical compartment attachable to a power distribution unit is disclosed. The isolated electrical compartment includes a housing defining a cavity, having a plurality of access doors, and having a plurality of conduit service openings positioned on a top surface or a side surface of the power distribution unit, each of the plurality of access doors corresponding to one of the plurality of conduit service openings. The isolated electrical compartment also includes a plurality of access compartments, each access compartment being accessible using one of the plurality of access doors.

### BRIEF DESCRIPTION OF THE DRAWINGS

The features and advantages of the embodiments of the present disclosure will become more apparent from the detailed description set forth below when taken in conjunction with the drawings. Naturally, the drawings and their associated descriptions illustrate example arrangements within the scope of the claims and do not limit the scope of the claims. Reference numbers are reused throughout the drawings to indicate correspondence between referenced elements.

FIG. 1 is a front perspective view of an isolated electrical compartment (IEC) attached to a top (can also be attached to a side) of a power distribution unit (POU) according to an embodiment of the invention.

FIG. 2 is an exploded front perspective view of the IEC of FIG. 1 according to an embodiment of the invention.

FIG. 3 is an exploded front view of a portion of the IEC of FIG. 1 illustrating a plurality of power terminals of the PDU according to an embodiment of the invention.

FIG. 4 is an exploded side view of a compartment with three exemplary power terminals shown below the compartment according to an embodiment of the invention.

FIG. 5 is a front perspective view of the IEC of FIG. 1 with the plurality of access doors removed to illustrate the plurality of compartments, the non-conductive side walls, and the plurality of power terminals according to an embodiment of the invention.

### DETAILED DESCRIPTION OF THE PREFERRED EMBODIMENTS

In the following detailed description, numerous specific details are set forth to provide an understanding of the present disclosure. It will be apparent, however, to one of ordinarily skilled in the art that elements of the present disclosure may be practiced without some of these specific details. In other instances, well-known structures and techniques have not been shown in detail to avoid unnecessarily obscuring the present disclosure.

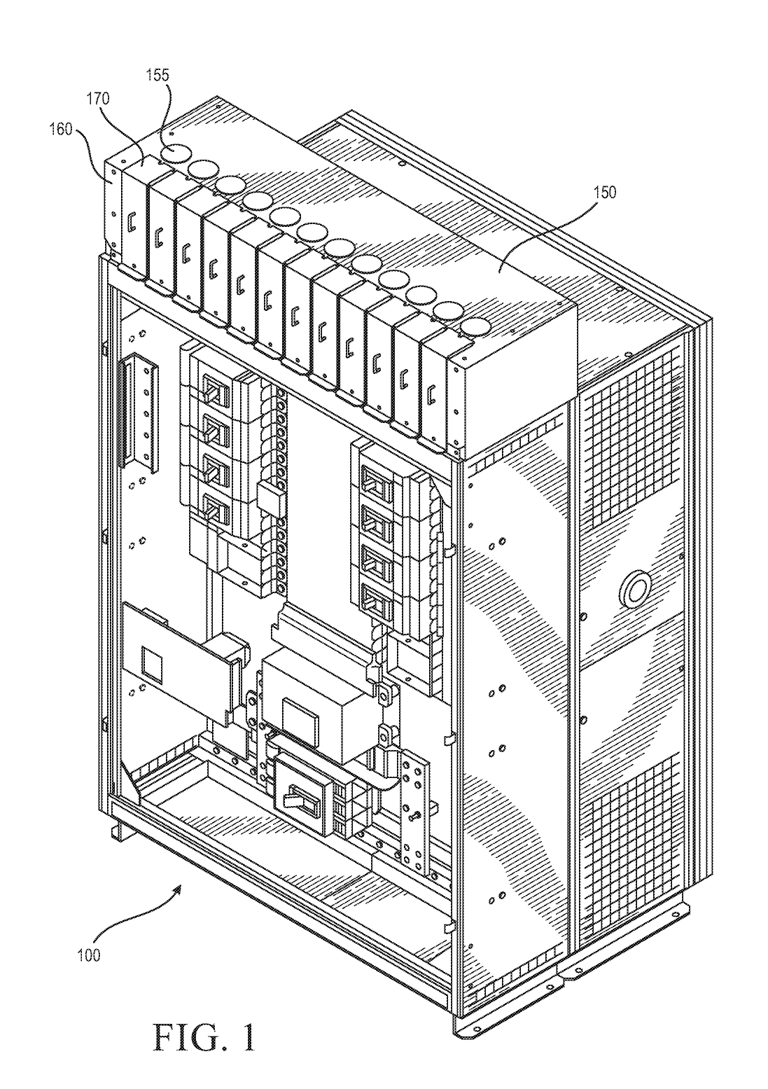

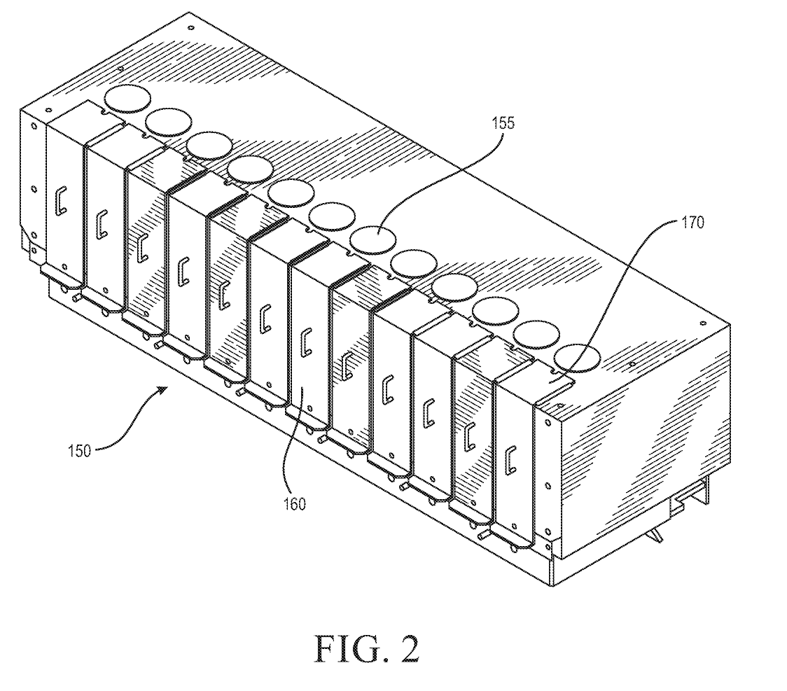

FIG. 1 is a front perspective view of an isolated electrical compartment (IEC) 150 attached to a top (can be attached to a side as well) of a power distribution unit (PDU) 100 according to an embodiment of the invention. FIG. 2 is an exploded front perspective view of the IEC 150 of FIG. 1 according to an embodiment of the invention. Referring to FIGS. 1 and 2, the IEC 150 includes a number of conduit service openings 155 and a number of access doors 160 for access to a number of compartments 170. In one embodiment, the number of conduit service openings 155, the number of access doors 160 and the number of compartments 170 are the same (e.g., all are 12). Each of the number of compartments 170 is formed in the shape of a rectangle or a square. Each access door 160 can be opened by a technician to allow the technician to repair or service the PDU 100 or to connect one or more cables to the PDU 100. Each access door 160 can have a unique locking system to allow only authorized technicians to access the corresponding compartment 170.

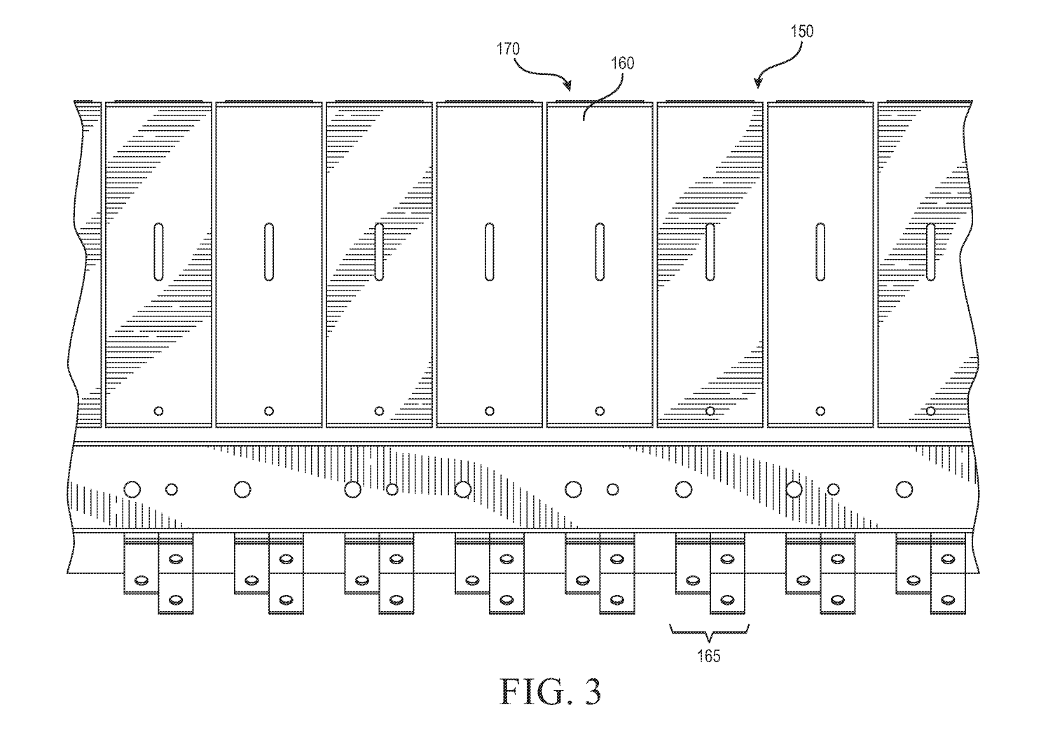

FIG. 3 is an exploded front view of a portion of the IEC 150 of FIG. 1 illustrating a plurality of power terminals 165 of the PDU 100 according to an embodiment of the invention. One or more cables (not shown) are connected to one or more power terminals 165 that are positioned below and/or within the number of compartments 170. The one or more cables can exit and enter the compartment 170 via the conduit service opening 155.

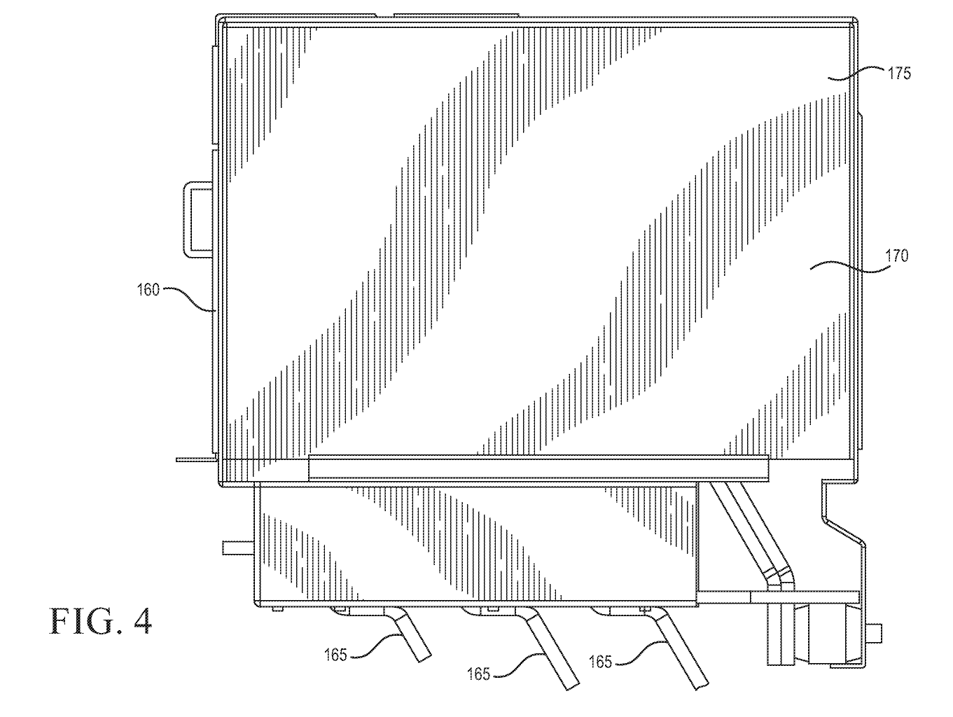

FIG. 4 is an exploded side view of a compartment 170 with three exemplary power terminals 165 shown below the compartment 170 according to an embodiment of the invention. Each compartment 170 has. non-conductive side walls 175 that prevent access to adjacent compartments. The plurality of access doors 160 can also be made of a non-conductive material. The advantage of non-conductive materials for the access doors 160 and the side walls 175 is that any contact by a power cable or a power terminal to the access doors 160 or the side walls 175 will not create an electrical shock or a dangerous situation. The non-conductive access doors 160 and side walls 175 prevent the transfer of high-voltage or current to the IEC 150 which can cause damage to the other components or compartment or electrocution of a technician working in this compartment or another compartment of the IEC 150.

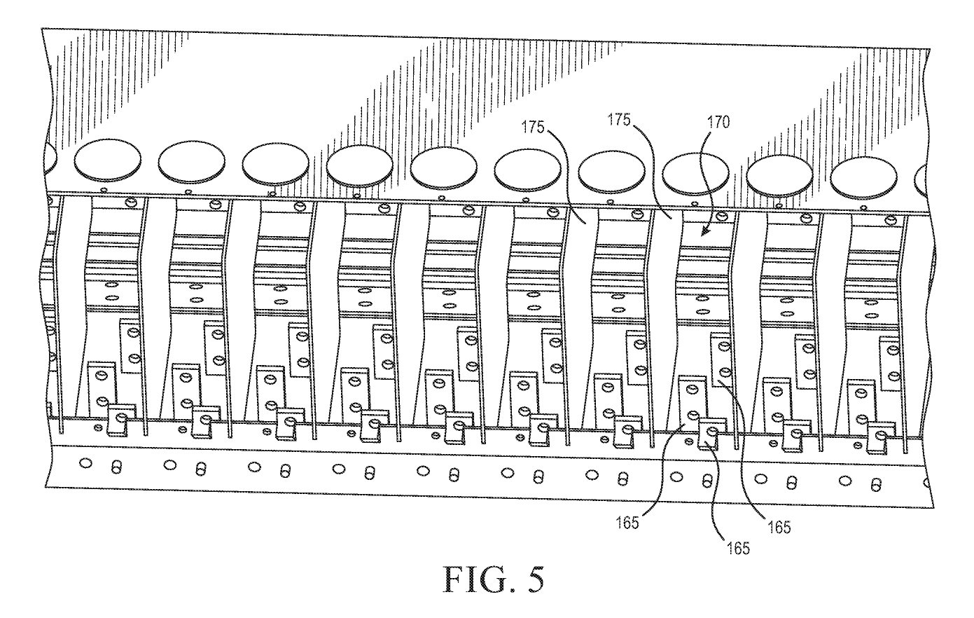

FIG. 5 is a front perspective view of the IEC 150 of FIG. 1 with the plurality of access doors 160 removed to illustrate the plurality of compartments 170, the non-conductive side walls 175, and the plurality of power terminals 165 according to an embodiment of the invention. One or more cables (not shown) are connected to one or more power terminals 165 that are positioned within the number of compartments 170. The one or more cables can exit and enter the compartment 170 via the conduit service opening 155, which is located at the top of the IEC 150 and to the rear of the compartment 170. The non-conductive side walls 175 are arranged substantially parallel to one another to form the plurality of compartments 170. Each individually isolated compartment 170 allows a technician to work on and connect and disconnect cables to the plurality of power terminals 165 within that compartment 170 without the danger of live cables and connections from nearby power terminals 165. Also, when the technician is working on cables and/or power terminals from a particular compartment 170, the power is cut-off to those cables and/or power terminals. The access door 160 can also be programmed to be locked when the cables and/or power terminals carry power or current and cannot be opened until power to the cables and/or power terminals are cut-off.

The foregoing description of the disclosed example embodiments is provided to enable any person of ordinary skill in the art to make or use the present invention. Various modifications to these examples will be readily apparent to those of ordinary skill in the art, and the principles disclosed herein may be applied ⋅ to other examples without departing from the spirit or scope of the present invention. The described embodiments are to be considered in all respects only as illustrative and not restrictive and the scope of the invention is, therefore, indicated by the following claims rather than by the foregoing description. All changes which come within the meaning and range of equivalency of the claims are to be embraced within their scope.

What is claimed is:

1. An isolated electrical compartment attachable to a power distribution unit, comprising:
a housing defining a cavity, having a plurality of access doors, and having a plurality of conduit service openings positioned on a top surface or a side surface of the power distribution unit, each of the plurality of access doors corresponding to one of the plurality of conduit service openings; and
a plurality of non-conductive walls positioned within the cavity and forming a plurality of access compartments, each access compartment being accessible using one of the plurality of access doors.

2. The isolated electrical compartment of claim 1, further comprising at least one electrical circuit link positioned within each of the plurality of access compartments, the at least one electrical circuit link being live or dead with electrical current or power.

3. The isolated electrical compartment of claim 2, further comprising a plurality of locks, each lock controlling one of the plurality of access doors for access to a corresponding access compartment when the at least one electrical circuit link is dead with electrical current or power.

4. The isolated electrical compartment of claim I, wherein each of the plurality of non-conductive walls separates a respective one of the access compartments from an adjacent access compartment.

5. An isolated electrical compartment attachable to a power distribution unit, comprising:
a housing defining a cavity, having a plurality of access doors, and having a plurality. of conduit service openings positioned on a top surface or a side surface of the power distribution unit;
a plurality of non-conductive walls positioned within the cavity and forming a plurality of access compartments, each access compartment being accessible using one of the plurality of access doors;
at least. one electrical circuit link positioned within each of the plurality of access compartments, the at least one electrical circuit link being live or dead with electrical current or power; and
a plurality of locks, each lock controlling one of the plurality of access doors for access to a corresponding access compartment when the at least one electrical circuit link is dead with electrical current or power.

6. The isolated electrical compartment of claim 1, wherein each of the plurality of non-conductive walls separates a respective one of the access compartments from an adjacent access compartment.
